(19) United States
(12) Patent Application Publication
(10) Pub. No.: US 2025/0287543 A1
(43) Pub. Date: Sep. 11, 2025

(54) FOAM HEAT SINKS USED IN IMMERSION COOLING SYSTEMS

(71) Applicant: Seagate Technology LLC, Fremont, CA (US)

(72) Inventors: Li Hong Zhang, Shugart (SG); Barish Chakravarty, Shugart (SG); Swee Chuan Gan, Shugart (SG); Xiong Liu, Shugart (SG)

(21) Appl. No.: 18/601,622

(22) Filed: Mar. 11, 2024

(51) Int. Cl. H05K 7/20; F28F 13/00

(52) U.S. Cl. CPC H05K 7/20409; F28F 13/003; H05K 7/20236

(57) ABSTRACT

An electronic cooling system includes an enclosure in which an electronic component is removably housed. A non-conductive liquid immerses or wets the electronic component. A foam heat sink is attached to a heat emitting surface of the electronic component. The foam heat sink is immersed or wetted by the liquid and provides a heat transfer path between the electronic component and the liquid. A porosity of the foam heat sink increases a coolant heat absorption rate from the heat emitting surface to the fluid.

### SUMMARY

The present disclosure is directed to systems and methods for increasing cooling efficiency in immersion cooling systems using foam heat sinks, including metal foam heat sinks.

In one embodiment, an electronic cooling system includes an enclosure in which an electronic component is removably housed. The electronic component comprises a data storage device. A non-conductive liquid immerses or wets the electronic component and a foam heat sink is attached to a heat emitting surface of the electronic component. The foam heat sink is immersed or wetted by the liquid and provides a heat transfer path between the electronic component and the liquid. A porosity of the foam heat sink increases a coolant heat absorption rate from the heat emitting surface to the fluid.

In another embodiment, a method of cooling a data storage device removably housed in an enclosure involves immersing or wetting the electronic component with a non-conductive liquid. The method further involves immersing or wetting a foam heat sink attached to a heat emitting surface of the electronic component. Heat is transferred from the electronic component to the liquid via the metal foam heat sink. A porosity of the foam heat sink increases a coolant heat absorption rate from the heat emitting surface to the fluid.

These and other features and aspects of various embodiments may be understood in view of the following detailed discussion and accompanying drawings.

### BRIEF DESCRIPTION OF THE DRAWINGS

The discussion below makes reference to the following figures, wherein the same reference number may be used to identify the similar/same component in multiple figures.

FIG. 1 is a perspective view showing an equipment rack according to an example embodiment;

FIG. 2 is a perspective view of an electronics enclosure according to an example embodiment;

FIG. 3 is a cutaway schematic view of a single-phase immersion cooling arrangement according to one or more embodiments;

FIG. 4 is a cutaway schematic view of a two-phase immersion cooling arrangement according to one or more embodiments;

FIG. 5 is a cutaway schematic view of a spray-wetted immersion cooling arrangement according to one or more embodiments;

FIG. 6 is a cutaway schematic view of a horizontal cooling arrangement with enclosure sidewall heat sinks according to one or more embodiments;

FIG. 7 is a schematic view showing how a metal foam can prevent forming surface gas barriers in a two-phase cooling arrangement according to one or more embodiments;

FIGS. 8 and 9 provide schematic views of open and closed cell metal foam according to example embodiments; and

FIG. 10 is a flowchart of a method according to an example embodiment.

### DETAILED DESCRIPTION

This disclosure generally relates to cooling for electronics, such as densely-packed, rack-mounted, computing equipment. The ever-increasing demand for Internet data services will drive the building of new data centers and retrofitting of existing data centers with significantly increased capabilities. Data centers typically house computer hardware in equipment racks. Inside each rack are one or more enclosures that often house tightly packed computer components such as computer boards (e.g., blade servers), graphics processing units, tensor processing units, storage units, and the like.

Many of the computer components generate heat. In particular, electrical computer components such as motherboards, central processing units (CPUs) and memory modules may generate notable heat due to use. Heating of the electrical components to high temperatures can cause irreversible damage, including shortened lifespan of components and dangers to the data storage facility overall. As such, there is a need for effective cooling of electronic components.

In this disclosure, apparatus and methods are described wherein foams, such as metal foams, may be utilized as heat sinks of hot electronic devices in single phase immersion cooling, two phase immersion cooling, and spray liquid cooling. In these embodiments, the metal foams can improve evaporation rate of the cooling liquid, prevent formation of thermal-insulating gas film on hot surfaces, and enhance flow convection of cooling liquid.

While metal foams are specifically described herein, it shall be understood that any foam material comprising a sufficiently high thermal conductivity and material compatibility with the cooling liquid may be utilized in any of the example embodiments as described herein. In terms of thermal conductivity, the minimum requirement may be 15 W m⁻¹ K⁻¹ (such as, for example, stainless steel, which has the thermal conductivity of ˜ 16 W m⁻¹ K⁻¹). Alternately or in addition, metal matrix composites and ceramics may also be suitably used as a heat sink as described in the below embodiments, such as for example AlSiC (thermal conductivity of 180-200 W m⁻¹ K⁻¹), AlSi (thermal conductivity of 161.5 W m⁻¹ K⁻¹), and AlN (thermal conductivity of 321 W m⁻¹ K⁻¹). Composite foams that utilize highly thermally conductive, non-metallic particles such as graphene particles.

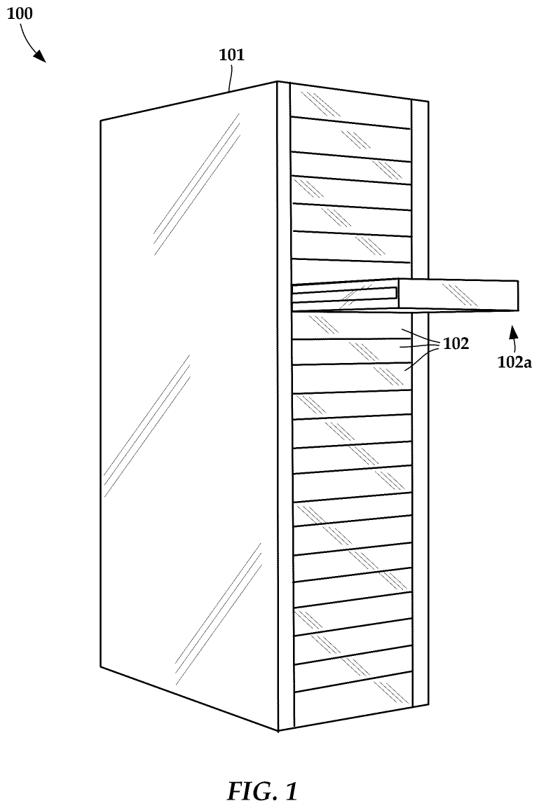

In FIG. 1, a perspective view shows a rack 100 assembly of the type that is often used in a data center, and which houses equipment according to one or more embodiments. The rack assembly 100 includes a rack frame 101 that mechanically houses a plurality of equipment enclosures 102, also referred to as units or chassis. The rack frame 101 (also often referred to just as the rack) includes structural supports (e.g., vertical and horizontal beams), covers, mounting points, floor supports, and the like.

The physical dimensions of the rack frame 101 and its constituent components are often referred to in terms of rack units ‘U’ or ‘RU’, which is defined as 1.75 inches of height. So a 4U enclosure has a 7-inch vertical dimension of at least the front panel, and a 44U rack can hold eleven 4U enclosures. Racks are readily available in different widths and depths. For example, 19 inch width and 24 inch depth enclosures are commonly available in a variety of heights. Depth sizes can vary depending on application. The present cable management systems are not limited to any particular rack or enclosure size, although may provide additional benefits for larger enclosure sizes, e.g., 2U and above.

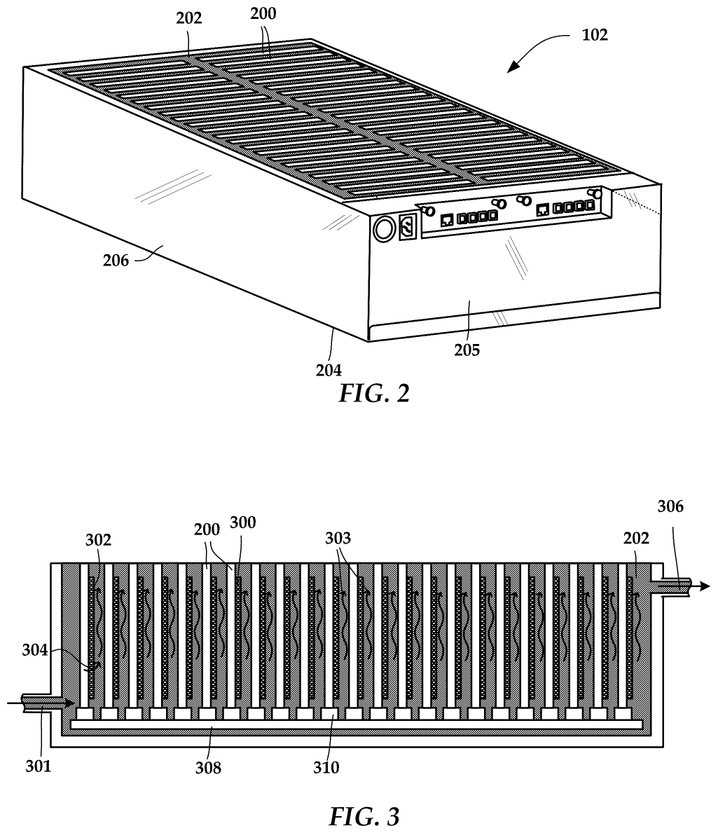

In FIG. 2, a perspective view shows a liquid-cooled electronics enclosure 102 according to an example embodiment. The electronics enclosure 102 may be housed in a rack as shown in FIG. 1, or be a standalone equipment enclosure. The electronics enclosure 102 houses one or more electronic components 200 that are removably attached within the enclosure 102. The electronic components 200 are immersed in non-conductive liquid 202 that fills an interior volume of the electronic enclosure. Generally, the use of the non-conductive liquid 202 allows for tighter packing of components within the enclosure compared to an air cooled enclosure, due to the higher thermal capacity of liquids compared to gases such as air.

The illustrated enclosure 102 has the form factor of a rack-mounted equipment cabinet, e.g., of the type used to house computing equipment such as system boards (e.g., motherboards with processors, memory, and other onboard devices), data storage devices (e.g., hard disk drives, solid-state drives), co-processors (e.g., graphics processors, tensor processors), random access memory (RAM) modules, and other specialized components (e.g., network switches). The non-conductive liquid may be a dielectric fluid such as 3M Novec™ Engineered Fluids, 3M™ Fluorinert™ Electronic Liquid, specially tailored hydrocarbon oils, and the like.

The enclosure 102 has outer surfaces (e.g., bottom 204, back 205, and side 206) that form a fluid impermeable container. This may involve using a welded structure, fastened-together panels with sealed joints, or other fabrication methods that prevent liquids from leaking out of the enclosure. The enclosure 102 will typically include a removable cover (not shown) to keep fluid from spilling out the top of the enclosure and to prevent contaminants from entering. The enclosure 102 may be smaller or larger than illustrated, e.g., ranging from a 1U enclosure to a full rack. The enclosure 102 may comprise just a portion of a larger enclosure, e.g., where some components in the larger enclosure are air cooled and others are immersion cooled.

In FIG. 3, a cutaway schematic view shows a single-phase immersion cooling arrangement according to one or more embodiments. In the single-phase immersion cooling arrangement, non-conductive liquid 202 partially or totally immersed one or more electronic components 200. The electronic components 200 include at least a first heat emitting surface 302. A metal foam heat sink 300 is attached to the heat emitting surface 302.

Due to the porous nature of the metal foam heat sink 300, the non-conductive liquid 202 permeates through the metal foam heat sink 300. The metal foam heat sink 300 has high thermal conductivity (e.g., formed of copper, aluminum, stainless steel or the like) and large surface area due to foam structures. Because of these properties, the metal foam heat sink 300 efficiently transfers heat from the heat emitting surface 302 to the surrounding fluid 202.

The enclosure in FIG. 3 also houses other components such as a backplane 308 and connectors. These components are also immersed in the non-conductive liquid 202 although are not shown with metal foam heat sinks. Generally, these components do not emit as much heat as components 200, but will still benefit from immersive cooling. In some cases, some components, e.g., integrated circuits, on a larger board such as the backplane 308 may have metal foam heat sinks selectively applied.

As the non-conductive liquid 202 permeates the metal foam heat sink 300 it heats up, which reduces the fluid density compared to the unheated surrounding fluid. This results in natural convection, where the heated fluid rises as indicated by arrows 303. Natural convection provides a heat transfer path 304 where non-conductive liquid 202 absorbs heat from the heat emitting surface 302 and flows out through the fluid outlet 306.

The liquid 202 can flow in and out of the enclosure in some embodiments via fluid inlet 301 fluid outlet 306. This arrangement can provide forced convention cooling, in which a pump or the like induces a flow through the enclosure. Liquid 202 from the outlet can be sent to an external heat exchanger (e.g., air cooled heat sink), cooling tower, or the like, which cools the liquid 202. The cooled liquid 202 can flow back in through the fluid inlet 301. An external heat exchanger is optional. For example, the liquid 202 can remain within the enclosure in some embodiments and transfer heat via the outer surfaces of the enclosure to ambient air.

Notably, in a single-phase embodiment as shown in FIG. 3, the non-conductive liquid 202 does not change state in significant amounts when transferring heat. For example, the liquid 202 does not boil due to the absorbed heat, although some evaporation or phase change may naturally occur within the enclosure. Generally, using single-phase, convective heat transfer can allow for a wider selection of cooling liquids, because single-phase cooling liquids do not require boiling points of the liquid 202 to be below the working temperature of the heat emitting surface 302.

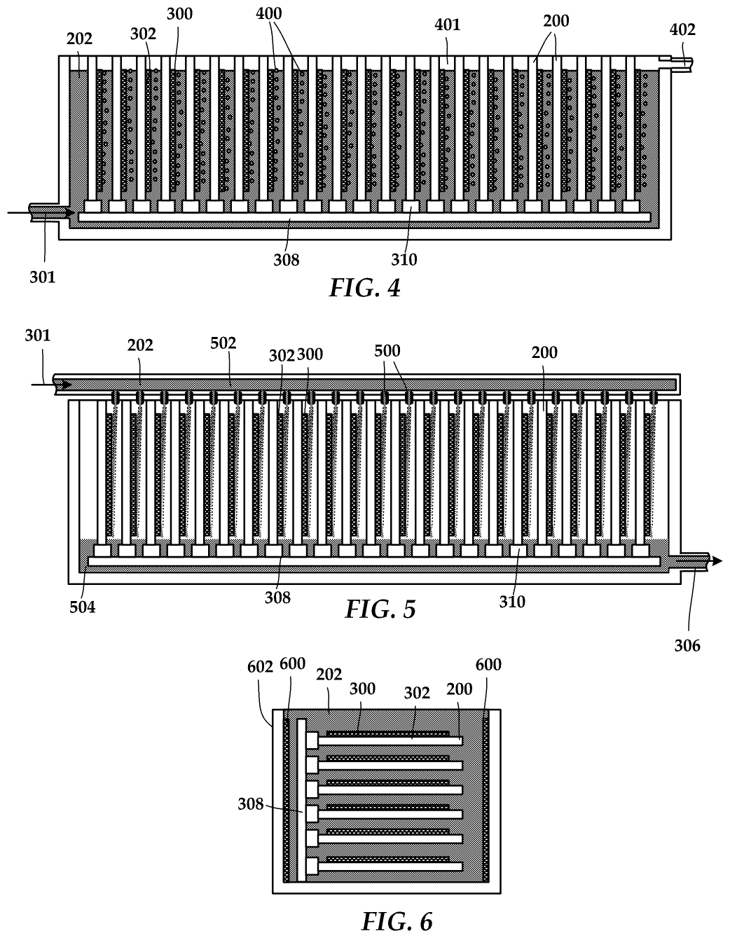

By contrast, in FIG. 4, a cutaway schematic view shows a two-phase immersion cooling arrangement according to one or more embodiments. In such an arrangement, the liquid 202 is selected to undergo a phase change (liquid to gas) as it cools the heat emitting surface 302 of the electronic component 200. This evaporation is indicated by gas bubbles 400, which gather in a space 401 at the top of the enclosure and may be removed by a gas outlet 402. The phase change from liquid to gas can absorb large amounts of thermal energy, and so a two-phase immersion system can be quite thermally efficient.

The absorbed heat can be transferred out of the enclosure via the gas outlet 402. Outside the enclosure, the evaporated gas may be cooled against by a heat exchanging method, such as for example a condenser, to allow return flow via the fluid inlet 301 into the larger liquid 202 volume. In other embodiments, the enclosure itself can transfer sufficient heat to ambient such that an external exchanger is not needed. In such a case, the gas may condense on a top cover (not shown) of the enclosure, where it forms droplets that fall and rejoin the rest of the liquid 202.

In FIG. 4 specifically, the electronic component 200 (which includes at least one heat emitting surface 302) is partially or totally submerged in liquid 202. Liquid 202 generally has a relatively low boiling point, such that any heat absorbed by the liquid 202 immersing the electronic component 200 may evaporate into a gas. The liquid 202 travels through the metal foam heat sink 300, which may be attached to the electronic component 200. As discussed above, due to the porous and thermally conductive nature of the metal foam heat sink 300, both gas and liquid can permeate through the metal foam heat sink 300 and transfer heat. As the non-conductive liquid 202 flows through the metal foam heat sink 300 and surrounds the electronic component 200, the liquid 202 evaporates into a gas which exits through the gas outlet. The phase change of the liquid 202 enables the heat transfer away from the electronic component 202. Generally, the gas caused by evaporation of the liquid 202 may be condensed into a fluid state by a condenser to once again flow through the fluid inlet and cool the electronic component 200.

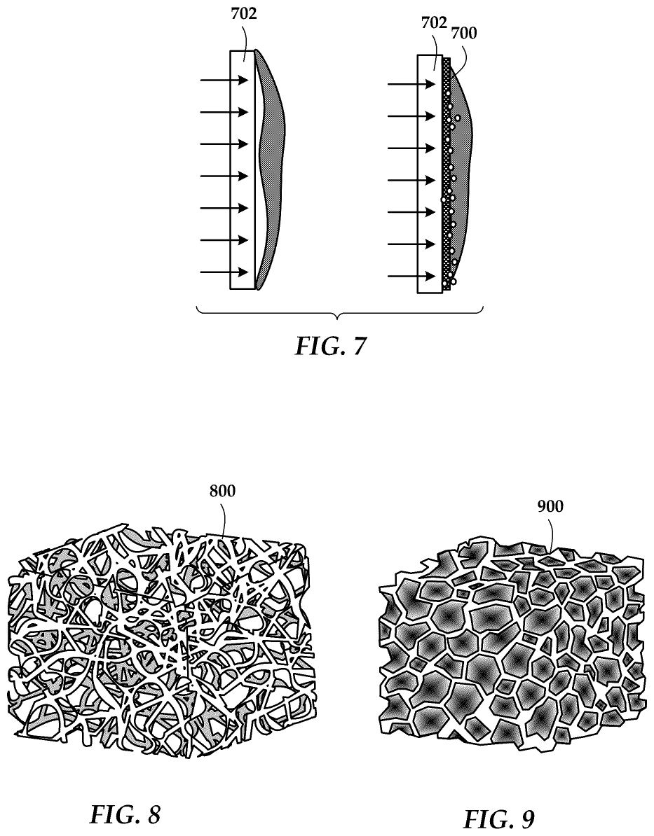

The metal foam heat sink 300 may enhance evaporation rate of the gas. The metal foam heat sink 300 may also prevent the formation of large gas barriers on the heated surface, which will be discussed below in regard to FIG. 7. Note that the cooling arrangement shown in FIG. 4 may achieve cooling via a combination of evaporation and natural or forced convection, which may depend on the boiling point of the fluid and the temperature of the components 200.

In FIG. 5, a cutaway schematic view shows a spray-wetted immersion cooling arrangement according to one or more embodiments. As in the single-phase immersion cooling arrangement example of FIG. 3 and two-phase immersion cooling arrangement example of FIG. 4, a non-conductive liquid 202 flows in through a fluid inlet 301 and travels through a manifold 502. A plurality of spray nozzles 500 are coupled to the manifold 502 and are configured to dispense, or spray, the non-conductive liquid 202 in a direction toward the fluidly permeable metal foam heat sink 300. The metal foam heat sink 300 is coupled to the electronic component 200 which includes at least one heat emitting surface 302.

If the spray-wetted immersion cooling arrangement utilizes single-phase immersion cooling, then after each spray nozzle 500 dispenses liquid 202 in the direction of the metal foam heat sink 300 and surrounds the electronic component 200. The heated fluid 202 collects at a bottom part 504 of the enclosure, where it can flow out through the fluid outlet 306. This may be considered a form of gravity forced convective heat transfer. As discussed above, in a single-phase immersion cooling system, the non-conductive liquid 202 does not change state, e.g., does not boil, even as convective heat transfer occurs and the liquid 202 absorbs heat from the heat emitting surface 302. Rather, heated liquid 202 exits through a fluid outlet 306 and may be circulated through a heat exchanger or cooling tower. A pump (not shown) may receive the liquid 202 from the fluid outlet 306 and/or an external heat exchanger, and then pressurize the liquid so that it can be fed back through the manifold 502 and nozzles 500. The pump may be internal to the enclosure in some embodiment, such that the external fluid outlet 306 is not used.

If the spray-wetted immersion cooling arrangement utilizes two-phase immersion cooling, then each spray of chilled liquid 202 via any of the plurality of spray nozzles 500 may eventually undergo a low temperature phase change (evaporation) which cools the electronic component 202. The phase change results in gas accumulating in the enclosure. Then, the evaporated gas may be cooled against by a heat exchanging method, such as for example an external condenser coupled to a gas outlet (not shown), to allow return flow via the fluid inlet 301 into the larger liquid 202 pool. In other embodiments the gas may cool against the wall of the enclosure, where it can re-accumulate at the bottom part 504 of the enclosure, where it is fed back into the manifold via an internal pump.

Dispensing chilled non-conductive liquid 202 via a plurality of spray nozzles may reduce costs associated with liquid immersion cooling techniques. For example, as liquid 202 is selectively dispensed toward the electronic component 200, there is no need to wholly or partially immerse the electronic component 200 in the (likely expensive) non-conductive liquid 202. Reducing the amount of cooling liquid can also reduce weight of the equipment.

In FIG. 6, a cutaway schematic view shows a cooling arrangement with enclosure sidewall heat sinks according to one or more embodiments. In FIG. 6, a second metal foam heat sink 600 may be affixed to a wall 602 of the enclosure 102 to provide a second means of heat transfer between the electronic component 200 and the non-conductive liquid 202. In this example, the electronic components 200 are shown mounted horizontally, although a vertical mounting may be used as in other embodiments.

As already discussed above, non-conductive liquid 202 may flow through the metal foam heat sink 300 attached to the electronic component 200 which comprises at least a first heat emitting surface 302. The second metal foam heat sink 600 may similarly allow non-conductive liquid 202 to flow through and transfer heat to the wall 602 of enclosure 102, which can then convect and/or radiate heat away from the enclosure. In this case, the wall 602 is acting as a heat conducting surface, as it is conducting heat out of the enclosure.

In FIG. 7, a schematic view shows how a metal foam heat sink 700 can prevent forming surface gas barriers in a two-phase cooling arrangement according to one or more embodiments. The metal foam heat sink 700 is attached to a heat emitting or heat conducting surface 702. The discontinuous structure of the metal foam heat sink 700 prevents the formation of large gas barriers 702 from forming as seen on the left hand side of the figure. These gas barriers 702 can have high thermal resistance which act as a cooling bottleneck and lowers the effectivity of two-phase cooling systems. Gas barriers 702 can form on single phase cooling systems as well, e.g., due to gases entrained in the fluid that accumulates on surfaces.

In FIGS. 8 and 9, perspective schematic views show examples of open and closed cell metal foam 800, 900 according to example embodiments. A metal foam, as described herein, generally comprises a highly porous structure with relatively low weight, high thermal conductivity, high gas permeability, and high surface area to volume ratio. Specifically, metal foams of close-cell or open-cell structures may have very surface areas due to the porous structures ranging from nano (<1 um), micro (1-1000 um) and macro (>1 mm) sizes The pores of the foams 800, 900 may be filled with gas, although liquid may displace the gas if submerged in the liquid.

The pores can be open as in foam 800, in which case each pore is interconnected to each of the plurality of pores in the metal structure. Alternately, the pores can be closed off, as in foam 900. A foam may include a combination of open and closed cells, and so may include some characteristics of both types.

Metal foam structures generally retain at least some physical properties of their base underlying material. For example, metal foam structures comprised of originally nonflammable material will remain nonflammable. Metal foam is generally recyclable to its base material. Metal foam structures may be formed of copper, graphene, nickel, steel, and aluminum, and other metal or metal alloys. Metal foam structures may include non-metallic material, such as carbon (e.g., graphene) and ceramic components. As porosity of the metal foam 300, 600 increases, non-conductive liquid 202 heat absorption rate from the heat emitting surface 302 to the liquid 202 also increases.

Metal micro-foam surfaces may additionally act as particle traps to clean liquid 202 by trapping particles formed in the liquid 202, thereby improving recyclability of the liquid 202 and mitigating environmental and financial costs of producing and disposing of liquid 202. This can also reduce the need for dedicated filtering mechanisms and associated pumps, which increase costs and reduce available space for devices.

The open cell metal foam of FIG. 8, with its high conductivity and fluid permeability, can be used as a heat exchanger. For example, when the metal foam is placed near a heat emitting surface 302, heat can be transferred to the metal foam via conduction and then removed from the foam with a fluid flow that can be a gas, a liquid, or a two phase mixture as seen in FIG. 4. FIG. 9 depicts an example embodiment of a closed-cell metal foam 900. Generally, each closed cell of the metal foam is filled with gas. A closed cell metal foam may have a higher weight than its corresponding open cell metal foam counterpart due additional material within the sidewalls.

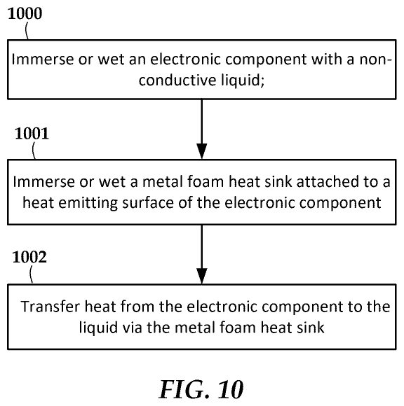

In FIG. 10, a flowchart shows a method of cooling an electronic component (e.g., a data storage device) removably housed in an enclosure according to an example embodiment. The method involves immersing or wetting 1000 the electronic component with a non-conductive liquid. The method also involves immersing or wetting 1001 a metal foam heat sink attached to a heat emitting surface of the electronic component. Heat is transferred 1002 from the electronic component to the liquid via the metal foam heat sink. A porosity of the metal foam increases a coolant heat absorption rate from the heat emitting surface to the fluid.

Unless otherwise indicated, all numbers expressing feature sizes, amounts, and physical properties used in the specification are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The use of numerical ranges by endpoints includes all numbers within that range (e.g., 1 to 5 includes 1, 1.5, 2, 2.75, 3, 3.80, 3, and 5) and any range within that range.

The foregoing description of the example embodiments has been presented for the purposes of illustration and description. It is not intended to be exhaustive or to limit the embodiments to the precise form disclosed. Many modifications and variations are possible in light of the above teaching. Any or all features of the disclosed embodiments can be applied individually or in any combination and are not meant to be limiting, but purely illustrative. It is intended that the scope of the invention be limited not with this detailed description, but rather determined by the claims appended hereto.

What is claimed is:

1. An electronic cooling system, comprising:
an enclosure in which an electronic component is removably housed, the electronic component comprising a data storage device;
a non-conductive liquid that immerses or wets the electronic component; and
a foam heat sink attached to a heat emitting surface of the electronic component, the foam heat sink immersed or wetted by the non-conductive liquid and providing a heat transfer path between the electronic component and the non-conductive liquid, a porosity of the foam heat sink increasing a coolant heat absorption rate from the heat emitting surface to the non-conductive liquid.

2. The electronic cooling system of claim 1, wherein the foam comprises material with compatibility to the non-conductive liquid and wherein the foam has a thermal conductivity of at least 15 W m⁻¹ K⁻¹.

3. The electronic cooling system of claim 1, wherein the foam comprises a metal foam.

4. The electronic cooling system of claim 1, wherein the non-conductive liquid evaporates as it removes heat from one or both of the foam heat sink and the electronic component.

5. The electronic cooling system of claim 2, wherein, the foam heat sink elevates an evaporation rate of the non-conductive liquid.

6. The electronic cooling system of claim 2, wherein the foam heat sink inhibits formation of a gas barrier on the heat emitting surface.

7. The electronic cooling system of claim 1, wherein the electronic cooling system comprises a single-phase immersion cooling system.

8. The electronic cooling system of claim 1, wherein the electronic cooling system comprises a two-phase immersion cooling system.

9. The electronic cooling system of claim 1, further comprising a plurality of spray nozzles, wherein each spray nozzle is configured to dispense the non-conductive liquid in a direction of the electronic component housed in the enclosure.

10. The electronic cooling system of claim 1, further comprising a second foam heat sink attached to a wall of the enclosure, the second foam heat sink providing a second heat transfer path between the electronic component and the non-conductive liquid.

11. The electronic cooling system of claim 1, wherein the non-conductive liquid is a dielectric liquid.

12. The electronic cooling system of claim 1, wherein the data storage device comprises a random access memory module.

13. The electronic cooling system of claim 1, wherein the data storage device comprises a solid state drive.

14. The electronic cooling system of claim 1, wherein the data storage device comprises a hard disk drive.

15. The electronic cooling system of claim 1, wherein the foam heat sink is comprised of a closed cell foam.

16. The electronic cooling system of claim 1, wherein the foam heat sink is comprised of an open cell foam.

17. A method of cooling a data storage device removably housed in an enclosure, the method comprising:
immersing or wetting an electronic component with a non-conductive liquid;
immersing or wetting a foam heat sink attached to a heat emitting surface of the electronic component; and
transferring heat from the electronic component to the non-conductive liquid via the foam heat sink, a porosity of the foam heat sink increasing a coolant heat absorption rate from the heat emitting surface to the non-conductive liquid.

18. The method of claim 17, wherein immersing or wetting the electronic component and the foam heat sink comprises spraying the non-conductive liquid in a direction of the electronic component.

19. The method of claim 17, wherein immersing or wetting the electronic component and the foam heat sink comprises immersing the electronic component and the metal foam heat sink, and wherein transferring heat from the electronic component to the non-conductive liquid comprises a phase change of the non-conductive liquid to a gas.

20. The method of claim 17, wherein immersing or wetting the electronic component and the foam heat sink comprises immersing the electronic component and the foam heat sink, and wherein transferring heat from the electronic component to the non-conductive liquid comprises forced or natural convection.
